(19) United States
(12) Patent Application Publication
(10) Pub. No.: US 2009/0080157 A1
(43) Pub. Date: Mar. 26, 2009

(54) METHOD, APPARATUS AND COMPUTER SYSTEM FOR AIR MOVER LID COOLING

(76) Inventors: Krishnakumar Varadarajan, Bangalore (IN); Anandaroop Bhattacharya, Bangalore (IN)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/858,462

(22) Filed: Sep. 20, 2007

(51) Int. Cl. G06F 1/20; H05K 7/20

(52) U.S. Cl. 361/697

(57) ABSTRACT

Some embodiments of a method, apparatus and computer system are described for cooling a lid with an air mover. A computer system may include a frame and a display with a heat spreader and one or more air movers. In some embodiments, the one or more air movers may include a piezoelectric fan, a synthetic jet, a centrifugal fan, a coaxial fan, an axial fan, or a propeller fan. Moreover, in some embodiments, the air movers may be integrated into or formed as part of the heat spreader's structure. Other embodiments are described.

### BACKGROUND

1. Technical Field

Some embodiments of the invention generally relate to the use of heat spreaders and air movers in a display to increase computer system cooling.

2. Discussion

In some computer systems, lid cooling has been used to increase the cooling capacity of the system. Lid cooling typically involves using the area inside a display and behind a display panel for the dissipation of thermal energy. As such, thermal energy is transferred from a component in the base of the computer system to the back of the display primarily through a heat pipe. The thermal energy is then spread and dissipated by natural convection.

FIG. 1 illustrates an example of a conventional lid cooling apparatus 100 as it may be generally understood and without regard to any specific implementations. The apparatus 100 provides for the transfer of thermal energy from a component 108 to a heat spreader 102, and thus provides for the dissipation of thermal energy or heat by natural convection in a lid 110.

More specifically, in FIG. 1, the apparatus 100 generally includes the heat spreader 102 thermally coupled to a heat pipe 104a. The heat spreader 102 is within the lid 110 and usually placed behind a panel 112, such as a liquid crystal display (LCD) panel. The heat pipe 104a is coupled to a hinge 106, which is also coupled to a heat pipe 104b. The heat pipe 104b is coupled to the component 108. The component 108 is typically found in the base of a computer system and near a heat-generating component.

There is, however, a need for cooling systems that, at least, have an increased ability to dissipate thermal energy in lids.

### BRIEF DESCRIPTION OF THE DRAWINGS

Various advantages of embodiments of the present invention will become apparent to one of ordinary skill in the art by reading the following specification and appended claims, and by referencing the following drawings, in which:

FIG. 1 illustrates an example of a conventional lid cooling apparatus;

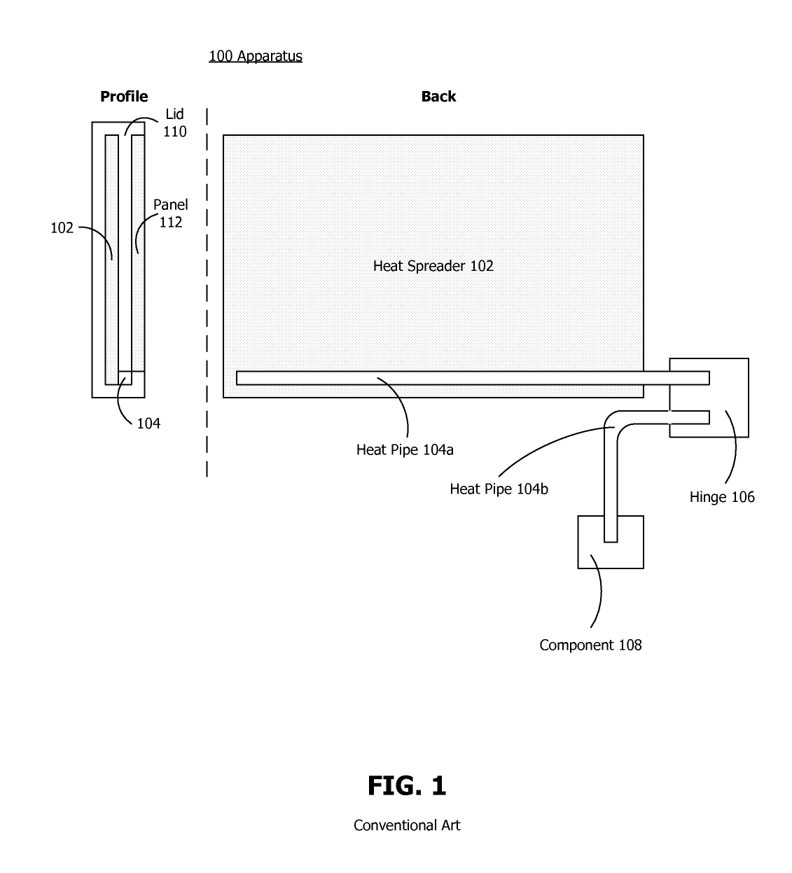

FIG. 2 illustrates an example of an air mover lid cooling apparatus according to some embodiments of the invention;

FIG. 3 illustrates an example of a computer system with air mover lid cooling according to some embodiments of the invention;

FIG. 4 illustrates examples of air movers according to some embodiments of the invention; and

FIG. 5 illustrates a flowchart for air mover lid cooling according to some embodiments of the invention.

### DETAILED DESCRIPTION

Reference is made to some embodiments of the invention, examples of which are illustrated in the accompanying drawings. While the invention will be described in conjunction with the embodiments, it will be understood that they are not intended to limit the invention to these embodiments. On the contrary, the invention is intended to cover alternatives, modifications and equivalents, which may be included within the spirit and scope of the invention as defined by the appended claims.

Moreover, in the following detailed description of the invention, numerous specific details are set forth in order to provide a thorough understanding of the invention. However, the invention may be practiced without these specific details. In other instances, well-known methods, procedures, components and circuits have not been described in detail as not to unnecessarily obscure aspects of the invention.

Some embodiments of the invention are directed to a method, apparatus and computer system for air mover lid cooling. In some embodiments of the invention, the computer system may include computing devices and electronic appliances, including, but not limited to, mobile computers, notebooks, laptops, personal digital assistants (PDAs), desktop computers, servers, such as blade or rack mounted servers, cellular telephones, personal electronic devices, and the like. Moreover, in some embodiments, the lids of these devices may take various forms, such as, but not limited to, a notebook lid, a lid of a mobile telephone, an external display, a television, etc., as one of ordinary skill in the relevant art would appreciate based at least on the teachings provided herein.

Indeed, reference in the specification to an embodiment or some embodiments of the invention means that a particular feature, structure or characteristic described in connection with the embodiment is included in at least one embodiment of the invention. Thus, the appearances of the phrase “in one embodiment” or “in some embodiments” appearing in various places throughout the specification are not necessarily all referring to the same embodiment, and are not meant to require the presence of other embodiments, which may be used exclusively, inclusively, or alternatively, as one of ordinary skill in the relevant art would appreciate based at least on the teachings provided herein.

Furthermore, while air and convection, natural convection, or passive cooling, are described with respect to the embodiments of the invention, one of ordinary skill in the relevant art would appreciate the application of the embodiments to other fluid mediums besides air, such as, but not limited to other gases, gaseous mixtures, liquids and other mediums which exhibit flow. In some embodiments, a medium or mediums other than air may be used, and certain implementation details may be altered as needed to accommodate the differences in density and flow rate of the medium as compared to air. Thus, while air is specifically discussed, it is not meant to preclude the application of embodiments of the invention with mediums other than air.

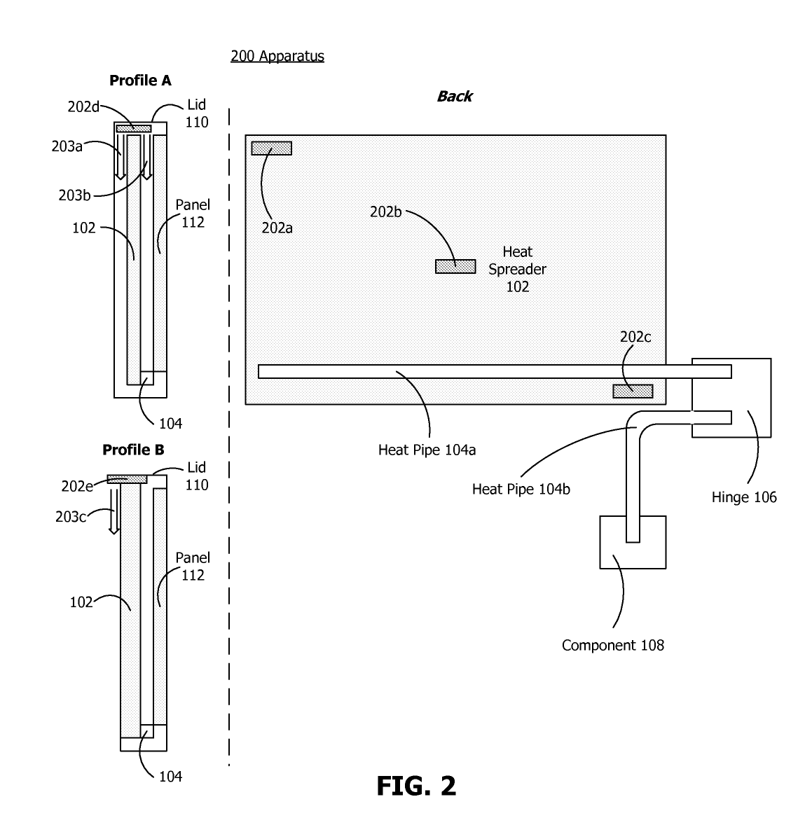

FIG. 2 illustrates an example of an air mover lid cooling apparatus 200 according to some embodiments of the invention. The apparatus 200 may provide for the transfer of thermal energy from a component 108 to a heat spreader 102, and thus may provide for the air mover assisted dissipation of thermal energy or heat by convection in a lid 110.

More specifically, in some embodiments, the apparatus 200 may include a heat pipe 104b in thermal contact with a component 108 to transfer thermal energy to a lid 110. In some embodiments, heat transfer mechanisms other than heat pipes may be used in place of or in combination with the heat pipe 104, as one of ordinary skill in the relevant art would appreciate based at least on the teachings provided herein. According to some embodiments, a heat spreader 102 in the lid 110 may transfer thermal energy from the component 108, and one or more air movers 202 may be in proximity with the heat spreader 102 to improve the heat transfer coefficient of the heat spreader 102.

In some embodiments, the one or more air movers 202, such as, but not limited to, air movers 202a, 202b, and 202c, may increase the effective thermal conductivity of the apparatus 200. According to some embodiments, the air movers 202 may be positioned in different positions in, on, or in proximity to, the lid 110. More specifically, as shown, the air mover 202b may be positioned in the relative middle of the lid 110. Furthermore, in some embodiments, as illustrated by air mover 202c, one or more of the air movers 202 may be positioned at the bottom of the lid 110. In these embodiments, the air movers 202 may be configured to provide or increase the flow of air over the heat spreader 102, as one of ordinary skill in the relevant art would appreciate based at least on the teachings provided herein. Moreover, in some embodiments, the heat pipe 104a may be positioned at relative middle or top of the heat spreader 102, as one of ordinary skill in the relative art would appreciate based at least on the teachings provided herein.

In some embodiments, the air movers 202 may be positioned along the heat spreader 102 as illustrated by air movers 202a-202c. Furthermore, in some embodiments, an air mover 202d may be positioned to move air on the interior side of the heat spreader 102, as shown by air flow 203b. Furthermore, in some embodiments, the air movers 202 may be positioned to move air on the exterior side of the heat spreader 102, as shown by air flow 203a. In some embodiments, an air mover 202e may be positioned to move air through the heat spreader 102, as illustrated by air flow 203c. As such, the heat spreader 102 may include one or more channels for the air flow 203c.

In some embodiments, the air movers 202 may be integrated into or formed as part of the structure of the heat spreader 102. As such, the air movers 202 may be constructed of the same or similar materials as the heat spread 102. In some embodiments, the air movers 202 and/or the heat spreader 102 may be formed into the lid 110, and thus may be the display's exterior portion.

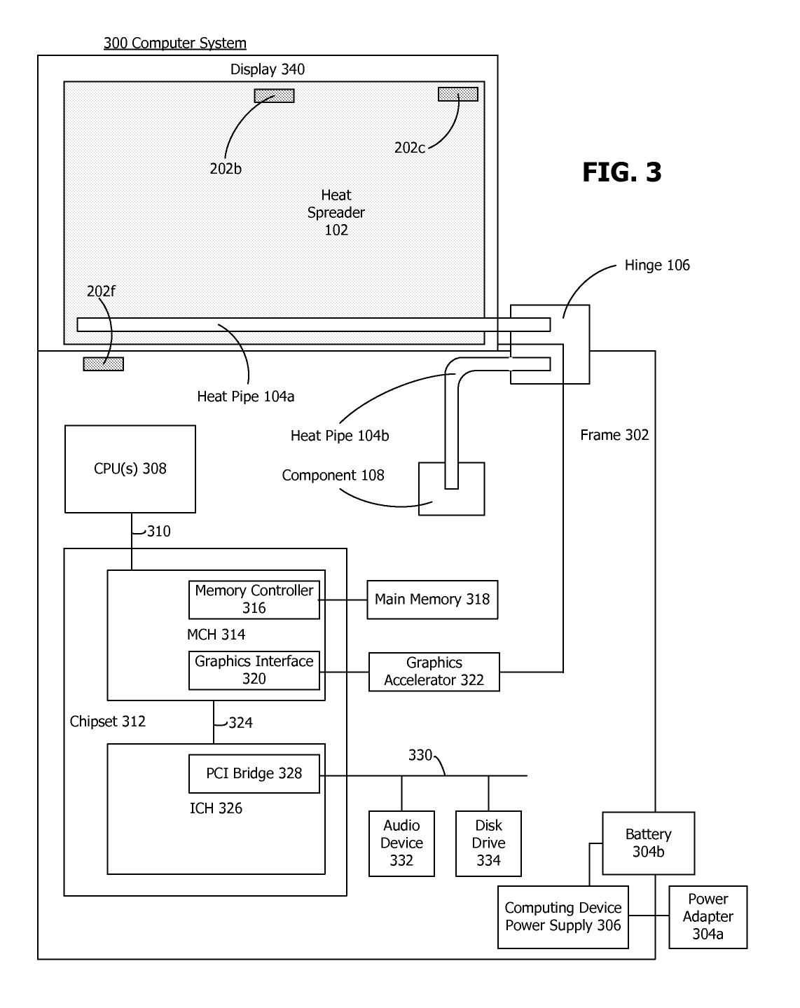

According to some embodiments, the apparatus 200 may also include a hinge 106, which may be thermally coupled to the heat pipe 104a. In some embodiments, the heat spreader 102 may be within the lid 110 and may be placed behind a panel 112, such as a liquid crystal display (LCD) panel. Moreover, in some embodiments, the hinge 106 may also be thermally coupled to a base heat pipe 104b, which may transfers thermal energy from a component 108. In some embodiments, the component 108, such as, but not limited to, a heat spreader or heat exchanger, may be found in the base or frame of a computer system and/or near a heat-generating component, as is described in greater detail with respect to FIG. 3.

As described elsewhere herein, in some embodiments, the one or more air movers 202 may include or comprise a piezoelectric fan, a synthetic jet, a centrifugal fan, a coaxial fan, an axial fan, or a propeller fan. As such, some of the air movers 202 may be of a different type than the other air movers 202 in the apparatus 200. Furthermore, according to some embodiments, the one or more air movers 202 may be positioned in proximity to the heat pipe 104b to move air over or through the heat spreader 102 and away from the heat pipe 104b, as one of ordinary skill in the relevant art would appreciate based at least on the teachings described herein.

According to some embodiments, the inclusion of the one or more air movers 202 may provide for an increase in the effective conductivity of the heat spreader 102. In some embodiments, the air movers 202 may also improve the uniformity of the temperature of the heat spreader. In some embodiments, the air movers 202 may allow the heat spreader 102 to attain a relatively isothermal state.

FIG. 3 illustrates an example of a computer system 300 with air mover lid cooling according to some embodiments of the invention. In some embodiments, the apparatus 200 may be implemented in the computer system 300, such as, but not limited to, within a display 340. In some embodiments, the computer system 300 includes a frame (or computing device) 302 and a power adapter 304 (e.g., to supply electrical power t the computing device 302). The computing device 302 may be any suitable computing device such as a laptop (or notebook) computer, a personal digital assistant, a desktop computing device (e.g., a workstation or a desktop computer), a rack-mounted computing device, and the like.

In some embodiments, one or more of the air movers 202, as shown by air mover 202f, may be positioned in the frame 202 (or otherwise in the base or body of the computer system). The air mover 202f may be positioned to provide or increase the flow of air over the lid 110 to enhance the effective transfer of thermal energy from the heat spreader 102.

Electrical power may be provided to various components of the computing device 302 (e.g., trough a computing device power supply 306) from one or more of the power sources. As such, in some embodiments, the power sources may include one or more battery packs, an alternating current (AC) outlet (e.g., through a transformer and/or adapor such as a power adapter 304), automotive power supplies, airplane power supplies, and the like. In some embodiments, the power adapter 304 may transform the power supply source output (e.g., the AC outlet voltage of about 110 VAC to 240 VAC) to a direct current (DC) voltage ranging between about 7 VDC to 12.6 VDC. Accordingly, the power adapter 304 may be an AC/DC adapter.

The computing device 302 may also include one or more central processing unit(s) (CPUs) 308 coupled to a bus 310. In some embodiments, the CPU 308 may be one or more processors in the Pentium® family of processors including the Pentium® II processor family, Pentium® III processors, Pentium® IV processors available from Intel® Corporation of Santa Clara, Calif. Alternatively, other CPUs may be used, such as Intel's Itanium®, XEON™, Celeron®, Core®, Core Duo®, and Core 2 Duo® processors. Also, one or more processors from other manufactures may be utilized. Moreover, the processors may have a single or multiple core design.

A chipset 312 may be coupled to the bus 310. The chipset 312 may include a memory control hub (MCH) 314. The MCH 314 may include a memory controller 316 that is coupled to a main system memory 318. The main system memory 318 stores data and sequences of instructions that are executed by the CPU 308, or any other device included in the system 300. In some embodiments, the main system memory 318 includes random access memory (RAM); however, the main system memory 318 may be implemented using other memory types such as dynamic RAM (DRAM), synchronous DRAM (SDRAM), and the like. Additional devices may also be coupled to the bus 310, such as multiple CPUs and/or multiple system memories.

The MCH 314 may also include a graphics interface 320 coupled to a graphics accelerator 322. In some embodiments, the graphics interface 320 is coupled to the graphics accelerator 322 via an accelerated graphics port (AGP). In an embodiment, a display (such as a flat panel or LCD display) 340 may be coupled to the graphics interface 320 through, for example, a signal converter that translates a digital representation of an image stored in a storage device such as video memory or system memory into display signals that are interpreted and displayed by the display. The display 340 signals produced by the display device may pass through various control devices before being interpreted by and subsequently displayed on the display.

A hub interface 324 couples the MCH 314 to an input/output control hub (ICH) 326. The ICH 326 provides an interface to input/output (I/O) devices coupled to the computer system 300. The ICH 326 may be coupled to a peripheral component interconnect (PCI) bus. Hence, the ICH 326 includes a PCI bridge 328 that provides an interface to a PCI bus 330. The PCI Bridge 328 provides a data path between the CPU 308 and peripheral devices. Additionally, other types of I/O interconnect topologies may be utilized such as the PCI Express™ architecture, available through Intel® Corporation of Santa Clara, Calif.

The PCI bus 330 may be coupled to an audio device 332 and one or more disk drive(s) 334. Other devices may be coupled to the PCI bus 330. In addition, the CPU 308 and the MCH 314 may be combined to form a single chip. Furthermore, the graphics accelerator 322 may be included within the MCH 314 in other embodiments. As yet another alternative, the MCH 314 and ICH 326 may be integrated into a single component, along with a graphics interface 320.

Additionally, other peripherals coupled to the ICH 326 may include, in various embodiments, integrated drive electronics (IDE) or small computer system interface (SCSI) hard drive(s), universal serial bus (USB) port(s), a keyboard, a mouse, parallel port(s), serial port(s), floppy disk drive(s), digital output support (e.g., digital video interface (DVI)), and the like. Hence, the computing device 302 may include volatile and/or nonvolatile memory.

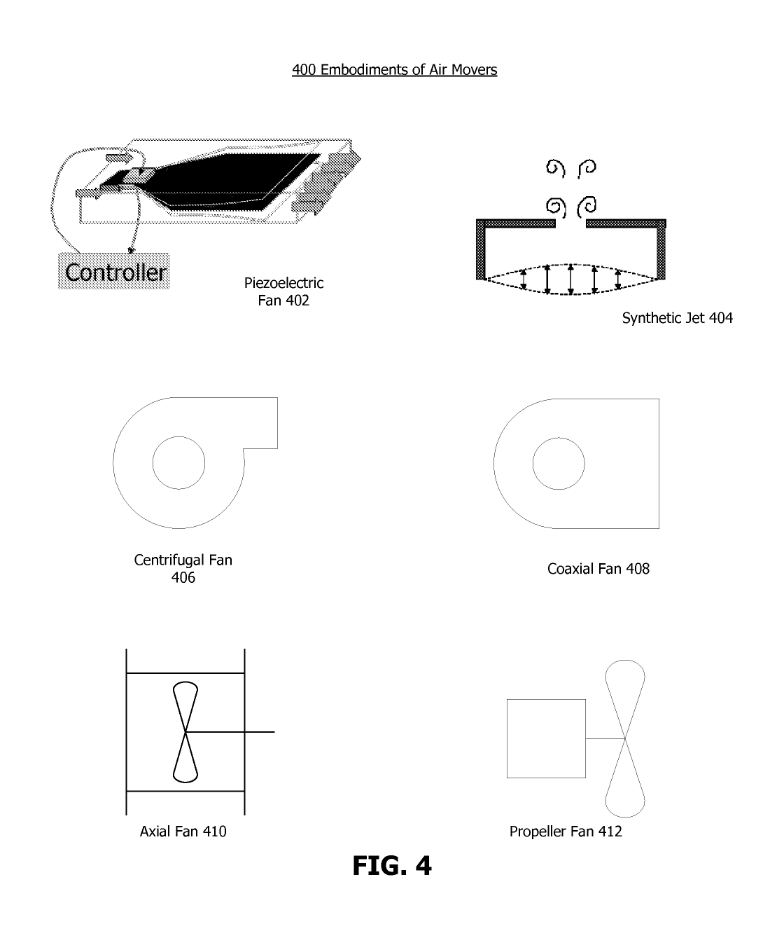

As may be evident from the system 300 and the embodiments described with respect to FIGS. 2, 4, and/or 5, some embodiments of the invention may be implemented in the system 300. Moreover, in some embodiments, the frame or computing device 302 may include more than one body or apparatus, as one of ordinary skill in the relevant art would appreciate based at least on the teachings described herein.

As one of ordinary skill would appreciate based at least on the teachings provided herein, the component 108 may be implemented in proximity or thermal contact with a memory, such as main memory 318, a hard drive, such as disk drive 334, a network card, a video graphics card, a motherboard, or a heat source. Moreover, in some embodiments, the apparatus 200 and the component 108 may be implemented within an electronic device, which may include a computer system 300, computing device, or electronic appliance, as one of ordinary skill in the relevant art would appreciate based at least on the teachings described herein.

FIG. 4 illustrates examples of air movers according to some embodiments of the invention. In some embodiments, the one or more air movers may be a piezoelectric fan 402, a synthetic jet 404, a centrifugal fan 406, a coaxial fan 408, an axial fan 410, or a propeller fan 412 in one or more places, as one of ordinary skill in the relevant art would appreciate based at least on the teachings described herein.

In some embodiments, the piezoelectric fans 402 may be low power, small, relative low noise, and/or solid-state devices that utilize piezoceramic patches bonded onto thin, low frequency, and/or flexible blades to drive the fan at one or more resonance frequencies. In some embodiments, the blades may create a streaming air flow directed at the heat spreader 102 and/or the lid 110.

In some embodiments, the synthetic jets 404 may provide periodic jets of air by use of a vibrating membrane that may include a piezoelectric or electromagnetic actuator. Due to the pulsating nature of the air flow, the jets 404 may introduce a stronger entrainment than steady jets of the same Reynolds number, as well as cause more mixing between the wall boundary layers and the rest of the air flow, as one of ordinary skill in the relevant art would appreciate based at least on the teachings provided herein. In some embodiments, the jets 404 may entrain cool air from the ambient air and blow it over the heat spreader 102 or the lid 110. The actuator may be placed in a housing with an outlet which can be preferentially directed towards the heat spreader 102 or the lid 110.

As such, in some embodiments, the air movers 202 may be different sizes and/or shapes that may make up a relatively small or large portion of the area of the heat spreader 102. According to some embodiments, the air movers 202 may be low power, and/or small devices, that may be placed on the lid 110. In effect, in some embodiments, the air movers 202 may form one or more streams of moving air on the surface of the heat spreader 102 or the lid 110. As such, the one or more air movers 202 may promote forced convective heat transfer, and thus may increase the passive dissipation of heat from the heat spreader 102 or the lid 110.

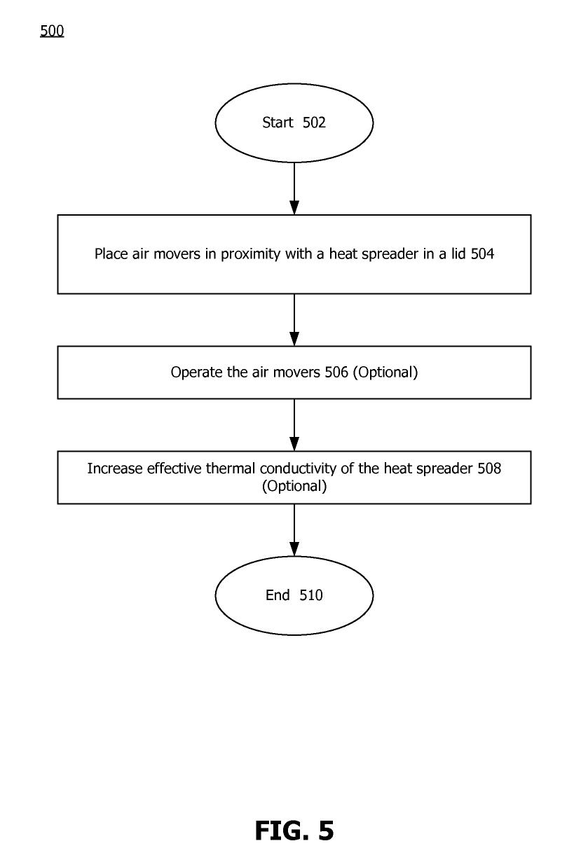

FIG. 5 illustrates a flowchart for air mover lid cooling according to some embodiments of the invention. The process 500 may begin at 502 and proceed to 504, where it may place one or more air movers in proximity with a heat spreader, such as, but not limited to heat spreader 102 or the lid 110. The process 500 may then optionally proceed to 506.

At 506, the process 500 may optionally operate the air mover. The process 500 may then increase transfer the thermal energy from the heat spreader, such as, but not limited to, heat spreader 102 or the lid 110. The process 500 may then optionally proceed to 508.

At 508, the process 500 may optionally increase the effective thermal conductivity of the heat spreader, such as, but not limited to, heat spreader 102 or the lid 110. The process 500 may then proceed to 510, where the process terminates. In some embodiments, the process 500 may begin again at any of 502, 504, 506, and/or 508, as one of ordinary skill in the relevant art would appreciate based at least on the teachings provided herein.

Embodiments of the present invention may be described in sufficient detail to enable those skilled in the art to practice the invention. Other embodiments may be utilized, and structural, logical, and intellectual changes may be made without departing from the scope of the present invention. Moreover, it is to be understood that various embodiments of the invention, although different, are not necessarily mutually exclusive. For example, a particular feature, structure, or characteristic described in one embodiment may be included within other embodiments. Those skilled in the art can appreciate from the foregoing description that the techniques of the embodiments of the invention can be implemented in a variety of forms.

Therefore, while the embodiments of this invention have been described in connection with particular examples thereof, the true scope of the embodiments of the invention should not be so limited since other modifications will become apparent to the skilled practitioner upon a study of the drawings, specification, and following claims.

What is claimed is:

1. An apparatus comprising:
a heat pipe in thermal contact with a component to transfer thermal energy to a lid;
a heat spreader in the lid to transfer thermal energy from the component; and
one or more air movers in proximity to the heat spreader to increase effective thermal conductivity of the heat spreader.

2. The apparatus of claim 1, further comprising:
a hinge thermally coupled to the heat pipe; and
a base heat pipe thermally coupled to the hinge, wherein the base heat pipe transfers thermal energy to the heat pipe from the component.

3. The apparatus of claim 1, wherein the one or more air movers are positioned to move air on a near side of the heat spreader that is near the panel.

4. The apparatus of claim 1, wherein the one or more air movers are positioned to move air on a far side of the heat spreader that is away from the panel.

5. The apparatus of claim 1, wherein the one or more air movers are positioned to move air through the heat spreader.

6. The apparatus of claim 1, wherein the one or more air movers include a piezoelectric fan, a synthetic jet, a centrifugal fan, a coaxial fan, an axial fan, or a propeller fan.

7. The apparatus of claim 1, wherein the one or more air movers are positioned in proximity to the heat pipe to move air over or through the heat spreader and away from the heat pipe.

8. The apparatus of claim 1, wherein the one or more air movers are positioned in proximity to the heat spreader to increase effective thermal uniformity of the heat spreader.

9. The apparatus of claim 1, wherein the one or more air movers are integrated into or formed as part of a structure from the heat spreader.

10. The apparatus of claim 1, wherein the component includes a heat spreader or heat exchanger.

11. A computer system comprising:
a frame; and
a heat pipe in thermal contact with a component to transfer thermal energy to a lid;
a heat spreader in the lid to transfer thermal energy from the component; and
one or more air movers in proximity to the heat spreader to increase effective thermal conductivity of the heat spreader.

12. The computer system of claim 11, further comprising:
a hinge thermally coupled to the heat pipe; and
a base heat pipe thermally coupled to the hinge, wherein the base heat pipe transfers thermal energy to the heat pipe from the component.

13. The computer system of claim 11, wherein the one or more air movers are positioned to move air on a near side of the heat spreader that is near the panel.

14. The computer system of claim 11, wherein the one or more air movers are positioned to move air on a far side of the heat spreader that is away from the panel.

15. The computer system of claim 11, wherein the one or more air movers are positioned to move air through the heat spreader.

16. The computer system of claim 11, wherein the one or more air movers include a piezoelectric fan, a synthetic jet, a centrifugal fan, a coaxial fan, an axial fan, or a propeller fan.

17. The computer system of claim 11, wherein the one or more air movers are positioned in proximity to the heat pipe to move air over or through the heat spreader and away from the heat pipe.

18. The computer system of claim 11, wherein the one or more air movers are positioned in proximity to the heat spreader to increase effective thermal uniformity of the heat spreader.

19. The computer system of claim 11, wherein the one or more air movers are integrated into or formed as part of a structure from the heat spreader.

20. The computer system of claim 11, wherein the computer system includes a mobile computer, a desktop computer, a server computer, or a handheld computer.

21. The computer system of claim 11, wherein the component is in thermal contact with one of a memory, a hard drive, a network card, a video graphics card, a motherboard, or a heat source.

22. A method comprising:
placing one or more air movers in proximity with a heat spreader.

23. The method of claim 22, further comprising:
operating the air movers.

24. The method of claim 23, further comprising:
increasing effective thermal conductivity of the heat spreader.
